(19) United States
(12) Patent Application Publication
(10) Pub. No.: US 2024/0095935 A1
(43) Pub. Date: Mar. 21, 2024

(54) DEEP LEARNING MODEL-BASED ALIGNMENT FOR SEMICONDUCTOR APPLICATIONS

(71) Applicant: KLA Corporation, Milpitas, CA (US)

(72) Inventors: Hong Chen, San Ramon, CA (US); Ziqi Fan, Milpitas, CA (US); Richard Wallingford, Ames, IA (US); Xiaochun Li, San Jose, CA (US); Sangbong Park, Danville, CA (US)

(21) Appl. No.: 18/178,528

(22) Filed: Mar. 5, 2023

Related U.S. Application Data
(60) Provisional application No. 63/399,787, filed on Aug. 22, 2022.

(51) Int. Cl. G06T 7/30; G06T 7/00

(52) U.S. Cl. CPC G06T 7/30; G06T 7/0006; G06T 7/001; G06T 2207/20081; G06T 2207/30148

(57) ABSTRACT

Methods and systems for deep learning alignment for semiconductor applications are provided. One method includes transforming design information for an alignment target on a specimen to a predicted image of the alignment target by inputting the design information into a deep learning model and aligning the predicted image to an image of the alignment target on the specimen generated by an imaging subsystem. The method also includes determining an offset between the predicted image and the image generated by the imaging subsystem based on results of the aligning and storing the determined offset as an align-to-design offset for use in a process performed on the specimen with the imaging subsystem.

### BACKGROUND OF THE INVENTION

### 1. Field of the Invention

The present invention generally relates to deep learning alignment for semiconductor applications. Certain embodiments relate to methods and systems for determining an offset for use in a process performed on a specimen.

### 2. Description of the Related Art

The following description and examples are not admitted to be prior art by virtue of their inclusion in this section.

An integrated circuit (IC) design may be developed using a method or system such as electronic design automation (EDA), computer aided design (CAD), and other IC design software. Such methods and systems may be used to generate the circuit pattern database from the IC design. The circuit pattern database includes data representing a plurality of layouts for various layers of the IC. Data in the circuit pattern database may be used to determine layouts for a plurality of reticles. A layout of a reticle generally includes a plurality of polygons that define features in a pattern on the reticle. Each reticle is used to fabricate one of the various layers of the IC. The layers of the IC may include, for example, a junction pattern in a semiconductor substrate, a gate dielectric pattern, a gate electrode pattern, a contact pattern in an interlevel dielectric, and an interconnect pattern on a metallization layer.

Fabricating semiconductor devices such as logic and memory devices typically includes processing a substrate such as a semiconductor wafer using a large number of semiconductor fabrication processes to form various features and multiple levels of the semiconductor devices. For example, lithography is a semiconductor fabrication process that involves transferring a pattern from a reticle to a resist arranged on a semiconductor wafer. Additional examples of semiconductor fabrication processes include, but are not limited to, chemical-mechanical polishing (CMP), etch, deposition, and ion implantation. Multiple semiconductor devices may be fabricated in an arrangement on a single semiconductor wafer and then separated into individual semiconductor devices.

Inspection processes are used at various steps during a semiconductor manufacturing process to detect defects on wafers to promote higher yield in the manufacturing process and thus higher profits. Inspection has always been an important part of fabricating semiconductor devices such as ICs. As design rules shrink, however, semiconductor manufacturing processes may be operating closer to the limitations on the performance capability of the processes. In addition, smaller defects can have an impact on the electrical parameters of the device as the design rules shrink, which drives more sensitive inspections. Therefore, as design rules shrink, the population of potentially yield relevant defects detected by inspection grows dramatically, and the population of nuisance defects detected by inspection also increases dramatically.

Inspection systems and methods are increasingly being designed to focus on the relationship between defect and design since it is the impact on the design for a specimen that will determine whether and how much a defect matters. For example, some methods have been developed for aligning inspection and design coordinates. One such method depends on the accuracy of the inspection system coordinate registration to design. Another such method involves conducting post-processing alignment on the inspection image patch and associated design clip.

Some currently used methods perform pixel-to-design alignment (PDA) training based on a setup die on a setup wafer, and a physics-based model is used to render images from design that are aligned to specimen images. For example, partial coherent physical model (PCM) based image rendering has been used to perform PDA on inspection tools. While such currently used methods for setting up and performing PDA have proved useful in a number of applications, there are a number of disadvantages to such methods and systems. For example, when the patterned features in the design get relatively dense, PCM based methods can run into difficulty in rendering optical images from design. In addition, on some specimen layers, PCM based methods can yield relatively low accuracy PDA results.

Accordingly, it would be advantageous to develop systems and methods for determining an offset for use in a process performed on a specimen that do not have one or more of the disadvantages described above.

### SUMMARY OF THE INVENTION

The following description of various embodiments is not to be construed in any way as limiting the subject matter of the appended claims.

One embodiment relates to a system configured to determine an offset for use in a process performed on a specimen. The system includes one or more computer subsystems and one or more components executed by the one or more computer subsystems. The one or more components include a deep learning (DL) model. The one or more computer subsystems are configured for transforming design information for an alignment target on a specimen to a predicted image of the alignment target by inputting the design information into a DL model. The computer subsystem(s) are also configured for aligning the predicted image to an image of the alignment target on the specimen generated by an imaging subsystem. In addition, the computer subsystem(s) are configured for determining an offset between the predicted image and the image generated by the imaging subsystem based on results of the aligning. The computer subsystem(s) are further configured for storing the determined offset as an align-to-design offset for use in a process performed on the specimen with the imaging subsystem. The system may be further configured as described herein.

Another embodiment relates to a computer-implemented method for determining an offset for use in a process performed on a specimen. The method includes the transforming, aligning, determining, and storing steps described above, which are performed by one or more computer systems. Each of the steps of the method may be performed as described further herein. In addition, the method described above may include any other step(s) of any other method(s) described herein. Furthermore, the method may be performed by any of the systems described herein.

An additional embodiment relates to a non-transitory computer-readable medium storing program instructions executable on one or more computer systems for performing a computer-implemented method for determining an offset for use in a process performed on a specimen. The computer-implemented method includes the steps of the method described above. The computer-readable medium may be further configured as described herein. The steps of the computer-implemented method may be performed as described further herein. In addition, the computer-implemented method for which the program instructions are executable may include any other step(s) of any other method(s) described herein.

### BRIEF DESCRIPTION OF THE DRAWINGS

Further advantages of the present invention will become apparent to those skilled in the art with the benefit of the following detailed description of the preferred embodiments and upon reference to the accompanying drawings in which:

FIGS. 1 and 2 are schematic diagrams illustrating side views of embodiments of a system configured as described herein;

FIGS. 3 and 5 are flow charts illustrating embodiments of steps that may be performed by the embodiments described herein;

FIG. 4 is a block diagram illustrating one embodiment of a deep learning (DL) model that may be included in the embodiments described herein; and

FIG. 6 is a block diagram illustrating one embodiment of a non-transitory computer-readable medium storing program instructions for causing computer system(s) to perform a computer-implemented method described herein.

While the invention is susceptible to various modifications and alternative forms, specific embodiments thereof are shown by way of example in the drawings and are herein described in detail. The drawings may not be to scale. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

The terms “design,” “design data,” and “design information” as used interchangeably herein generally refer to the physical design (layout) of an IC or other semiconductor device and data derived from the physical design through complex simulation or simple geometric and Boolean operations. The design may include any other design data or design data proxies described in commonly owned U.S. Pat. No. 7,570,796 issued on Aug. 4, 2009 to Zafar et al. and U.S. Pat. No. 7,676,077 issued on Mar. 9, 2010 to Kulkarni et al., both of which are incorporated by reference as if fully set forth herein. In addition, the design data can be standard cell library data, integrated layout data, design data for one or more layers, derivatives of the design data, and full or partial chip design data. Furthermore, the “design,” “design data,” and “design information” described herein refers to information and data that is generated by semiconductor device designers in a design process and is therefore available for use in the embodiments described herein well in advance of printing of the design on any physical specimens such as reticles and wafers.

Turning now to the drawings, it is noted that the figures are not drawn to scale. In particular, the scale of some of the elements of the figures is greatly exaggerated to emphasize characteristics of the elements. It is also noted that the figures are not drawn to the same scale. Elements shown in more than one figure that may be similarly configured have been indicated using the same reference numerals. Unless otherwise noted herein, any of the elements described and shown may include any suitable commercially available elements.

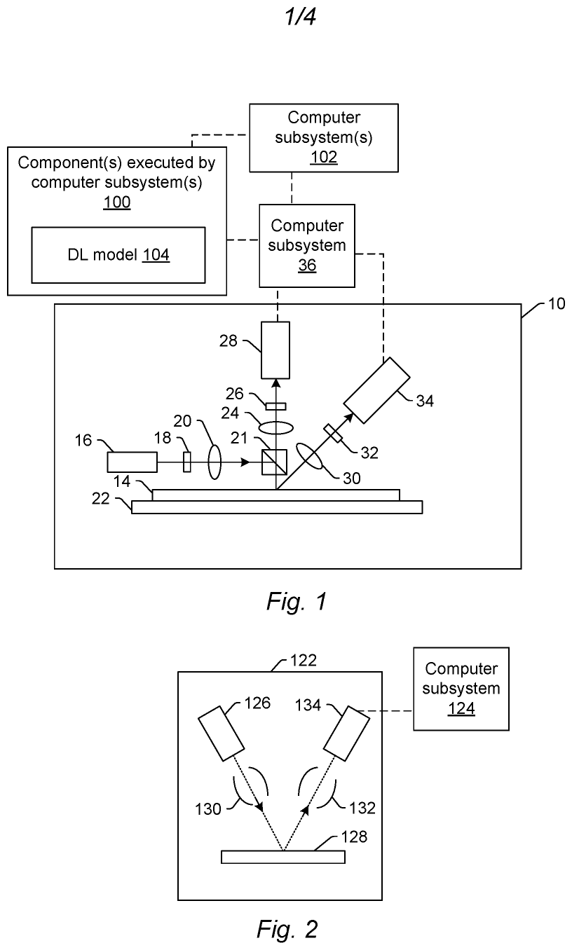

One embodiment relates to a system configured to determine an offset for use in a process performed on a specimen. The offsets determined by the embodiments described herein can be used for applications such as IC design to optical (or other) image alignment through deep learning (DL) models. One embodiment of such a system is shown in FIG. 1. The system includes one or more computer subsystems (e.g., computer subsystems 36 and 102) and one or more components 100 executed by the one or more computer subsystems. The one or more components include DL model 104, which is configured as described further herein.

In some embodiments, the specimen is a wafer. The wafer may include any wafer known in the semiconductor arts. Although some embodiments may be described herein with respect to a wafer or wafers, the embodiments are not limited in the specimens for which they can be used. For example, the embodiments described herein may be used for specimens such as reticles, flat panels, personal computer (PC) boards, and other semiconductor specimens.

In some embodiments, the system includes an imaging subsystem that includes at least an energy source and a detector. The energy source is configured to generate energy that is directed to a specimen. The detector is configured to detect energy from the specimen and to generate output responsive to the detected energy.

In one embodiment, the imaging subsystem is a light-based imaging subsystem. In one embodiment shown in FIG. 1, imaging subsystem 10 includes an illumination subsystem configured to direct light to specimen 14. The illumination subsystem includes at least one light source (e.g., light source 16 shown in FIG. 1). The illumination subsystem is configured to direct the light to the specimen at one or more angles of incidence, which may include one or more oblique angles and/or one or more normal angles. As shown in FIG. 1, light from light source 16 is directed through optical element 18 and then lens 20 to beam splitter 21, which directs the light to specimen 14 at a normal angle of incidence. The angle of incidence may include any suitable angle of incidence, which may vary depending on, for instance, characteristics of the specimen, the defects to be detected on the specimen, the measurements to be performed on the specimen, etc.

The illumination subsystem may be configured to direct the light to the specimen at different angles of incidence at different times. For example, the imaging subsystem may be configured to alter one or more characteristics of one or more elements of the illumination subsystem such that the light can be directed to the specimen at an angle of incidence that is different than that shown in FIG. 1. In one such example, the imaging subsystem may be configured to move light source 16, optical element 18, and lens 20 such that the light is directed to the specimen at a different angle of incidence.

The imaging subsystem may be configured to direct light to the specimen at more than one angle of incidence at the same time. For example, the imaging subsystem may include more than one illumination channel, one of the illumination channels may include light source 16, optical element 18, and lens 20 as shown in FIG. 1 and another of the illumination channels (not shown) may include similar elements, which may be configured differently or the same, or may include at least a light source and possibly one or more other components such as those described further herein. If such light is directed to the specimen at the same time as the other light, one or more characteristics (e.g., wavelength, polarization, etc.) of the light directed to the specimen at different angles of incidence may be different such that light resulting from illumination of the specimen at the different angles of incidence can be discriminated from each other at the detector(s).

The illumination subsystem may include only one light source (e.g., source 16 shown in FIG. 1) and light from the light source may be separated into different optical paths (e.g., based on wavelength, polarization, etc.) by one or more optical elements (not shown) of the illumination subsystem. Light in each of the different optical paths may then be directed to the specimen. Multiple illumination channels may be configured to direct light to the specimen at the same time or at different times (e.g., when different illumination channels are used to sequentially illuminate the specimen). In another instance, the same illumination channel may be configured to direct light to the specimen with different characteristics at different times. For example, optical element 18 may be configured as a spectral filter and the properties of the spectral filter can be changed in a variety of different ways (e.g., by swapping out the spectral filter) such that different wavelengths of light can be directed to the specimen at different times. The illumination subsystem may have any other suitable configuration known in the art for directing light having different or the same characteristics to the specimen at different or the same angles of incidence sequentially or simultaneously.

Light source 16 may include a broadband plasma (BBP) light source. In this manner, the light generated by the light source and directed to the specimen may include broadband light. However, the light source may include any other suitable light source such as a laser, which may be any suitable laser known in the art and may be configured to generate light at any suitable wavelength(s) known in the art. The laser may be configured to generate light that is monochromatic or nearly-monochromatic. In this manner, the laser may be a narrowband laser. The light source may also include a polychromatic light source that generates light at multiple discrete wavelengths or wavebands.

Light from optical element 18 may be focused to beam splitter 21 by lens 20. Although lens 20 is shown in FIG. 1 as a single refractive optical element, in practice, lens may include a number of refractive and/or reflective optical elements that in combination focus the light from the optical element to the specimen. The illumination subsystem shown in FIG. 1 and described herein may include any other suitable optical elements (not shown). Examples of such optical elements include, but are not limited to, polarizing component(s), spectral filter(s), spatial filter(s), reflective optical element(s), apodizer(s), beam splitter(s), aperture(s), and the like, which may include any such suitable optical elements known in the art. In addition, the system may be configured to alter one or more elements of the illumination subsystem based on the type of illumination to be used for inspection, metrology, etc.

The imaging subsystem may also include a scanning subsystem configured to cause the light to be scanned over the specimen. For example, the imaging subsystem may include stage 22 on which specimen 14 is disposed during inspection, measurement, etc. The scanning subsystem may include any suitable mechanical and/or robotic assembly (that includes stage 22) that can be configured to move the specimen such that the light can be scanned over the specimen. In addition, or alternatively, the imaging subsystem may be configured such that one or more optical elements of the imaging subsystem perform some scanning of the light over the specimen. The light may be scanned over the specimen in any suitable fashion.

The imaging subsystem further includes one or more detection channels. At least one of the one or more detection channels includes a detector configured to detect light from the specimen due to illumination of the specimen by the imaging subsystem and to generate output responsive to the detected light. For example, the imaging subsystem shown in FIG. 1 includes two detection channels, one formed by collector 24, element 26, and detector 28 and another formed by collector 30, element 32, and detector 34. As shown in FIG. 1, the two detection channels are configured to collect and detect light at different angles of collection. In some instances, one detection channel is configured to detect specularly reflected light, and the other detection channel is configured to detect light that is not specularly reflected (e.g., scattered, diffracted, etc.) from the specimen. However, two or more of the detection channels may be configured to detect the same type of light from the specimen (e.g., specularly reflected light). Although FIG. 1 shows an embodiment of the imaging subsystem that includes two detection channels, the imaging subsystem may include a different number of detection channels (e.g., only one detection channel or two or more detection channels). Although each of the collectors are shown in FIG. 1 as single refractive optical elements, each of the collectors may include one or more refractive optical element(s) and/or one or more reflective optical element(s).

The one or more detection channels may include any suitable detectors known in the art. For example, the detectors may include photo-multiplier tubes (PMTs) or any other suitable non-imaging detectors known in the art. If the detectors are non-imaging detectors, each of the detectors may be configured to detect certain characteristics of the scattered light such as intensity but may not be configured to detect such characteristics as a function of position within the imaging plane. As such, the output that is generated by each of the detectors included in each of the detection channels may be signals or data, but not image signals or image data. In such instances, a computer subsystem such as computer subsystem 36 of the system may be configured to generate images of the specimen from the non-imaging output of the detectors.

FIG. 1 is provided herein to generally illustrate a configuration of an imaging subsystem that may be included in the system embodiments described herein. Obviously, the imaging subsystem configuration described herein may be altered to optimize the performance of the system as is normally performed when designing a commercial inspection, metrology, etc. system. In addition, the systems described herein may be implemented using an existing inspection or metrology system (e.g., by adding functionality described herein to an existing inspection or metrology system) such as the 29xx and 39xx series of tools, the SpectraShape family of tools, and the Archer series of tools that are commercially available from KLA Corp., Milpitas, Calif. For some such systems, the embodiments described herein may be provided as optional functionality of the system (e.g., in addition to other functionality of the system). Alternatively, the imaging subsystem described herein may be designed “from scratch” to provide a completely new system.

Computer subsystem 36 of the system may be coupled to the detectors of the imaging subsystem in any suitable manner (e.g., via one or more transmission media, which may include “wired” and/or “wireless” transmission media) such that the computer subsystem can receive the output generated by the detectors during scanning of the specimen. Computer subsystem 36 may be configured to perform a number of functions using the output of the detectors as described herein and any other functions described further herein. This computer subsystem may be further configured as described herein.

This computer subsystem (as well as other computer subsystems described herein) may also be referred to herein as computer system(s). Each of the computer subsystem(s) or system(s) described herein may take various forms, including a personal computer system, image computer, mainframe computer system, workstation, network appliance, Internet appliance, or other device. In general, the term “computer system” may be broadly defined to encompass any device having one or more processors, which executes instructions from a memory medium. The computer subsystem(s) or system(s) may also include any suitable processor known in the art such as a parallel processor. In addition, the computer subsystem(s) or system(s) may include a computer platform with high speed processing and software, either as a standalone or a networked tool.

If the system includes more than one computer subsystem, the different computer subsystems may be coupled to each other such that images, data, information, instructions, etc. can be sent between the computer subsystems as described further herein. For example, computer subsystem 36 may be coupled to computer subsystem(s) 102 (as shown by the dashed line in FIG. 1) by any suitable transmission media, which may include any suitable wired and/or wireless transmission media known in the art. Two or more of such computer subsystems may also be effectively coupled by a shared computer-readable storage medium (not shown).

In another embodiment, the imaging subsystem is an electron beam imaging subsystem. In this manner, the energy source may be an electron beam source. In one such embodiment shown in FIG. 2, the imaging subsystem includes electron column 122, which is coupled to computer subsystem 124.

As also shown in FIG. 2, the electron column includes electron beam source 126 configured to generate electrons that are focused to specimen 128 by one or more elements 130. The electron beam source may include, for example, a cathode source or emitter tip, and one or more elements 130 may include, for example, a gun lens, an anode, a beam limiting aperture, a gate valve, a beam current selection aperture, an objective lens, and a scanning subsystem, all of which may include any such suitable elements known in the art.

Electrons returned from the specimen (e.g., secondary electrons) may be focused by one or more elements 132 to detector 134. One or more elements 132 may include, for example, a scanning subsystem, which may be the same scanning subsystem included in element(s) 130.

The electron column may include any other suitable elements known in the art. In addition, the electron column may be further configured as described in U.S. Pat. No. 8,664,594 issued Apr. 4, 2014 to Jiang et al., U.S. Pat. No. 8,692,204 issued Apr. 8, 2014 to Kojima et al., U.S. Pat. No. 8,698,093 issued Apr. 15, 2014 to Gubbens et al., and U.S. Pat. No. 8,716,662 issued May 6, 2014 to MacDonald et al., which are incorporated by reference as if fully set forth herein.

Although the electron column is shown in FIG. 2 as being configured such that the electrons are directed to the specimen at an oblique angle of incidence and are scattered from the specimen at another oblique angle, it is to be understood that the electron beam may be directed to and scattered from the specimen at any suitable angles. In addition, the electron beam subsystem may be configured to use multiple modes to generate images of the specimen (e.g., with different illumination angles, collection angles, etc.). The multiple modes of the electron beam subsystem may be different in any image generation parameter(s) of the subsystem.

Computer subsystem 124 may be coupled to detector 134 as described above. The detector may detect electrons returned from the surface of the specimen thereby generating output used by the computer subsystem(s) to form electron beam images of the specimen, which may include any suitable electron beam images. Computer subsystem 124 may be configured to perform any of the functions described herein using the output of the detector and/or the electron beam images. Computer subsystem 124 may be configured to perform any additional step(s) described herein. A system that includes the imaging subsystem shown in FIG. 2 may be further configured as described herein.

FIG. 2 is provided herein to generally illustrate a configuration of an electron beam-based imaging subsystem that may be included in the embodiments described herein. As with the optical subsystem described above, the electron beam subsystem configuration described herein may be altered to optimize the performance of the subsystem as is normally performed when designing a commercial inspection or metrology system. In addition, the systems described herein may be implemented using an existing inspection, metrology, or other system (e.g., by adding functionality described herein to an existing system) such as tools that are commercially available from KLA. For some such systems, the embodiments described herein may be provided as optional functionality of the system (e.g., in addition to other functionality of the system). Alternatively, the system described herein may be designed “from scratch” to provide a completely new system.

The imaging subsystem may alternatively be an ion beam-based subsystem. Such an imaging subsystem may be configured as shown in FIG. 2 except that the electron beam source may be replaced with any suitable ion beam source known in the art. In one embodiment, therefore, the energy directed to the specimen includes ions. In addition, the imaging subsystem may be any other suitable ion beam-based imaging subsystem such as those included in commercially available focused ion beam (FIB) systems, helium ion microscopy (HIM) systems, and secondary ion mass spectroscopy (SIMS) systems.

The imaging subsystems described herein may be configured to generate images for the specimen with multiple modes. In general, a “mode” is defined by the values of parameters of the imaging subsystem used for generating the images of the specimen. Therefore, modes may be different in the values for at least one of the parameters of the imaging subsystem (other than position on the specimen at which the output is generated). For example, in an optical subsystem, different modes may use different wavelength(s) of light for illumination. The modes may be different in the illumination wavelength(s) as described further herein (e.g., by using different light sources, different spectral filters, etc.) for different modes. In another embodiment, different modes may use different illumination channels of the optical subsystem. For example, as noted above, the optical subsystem may include more than one illumination channel. As such, different illumination channels may be used for different modes. The modes may be different in any one or more alterable parameters (e.g., illumination polarization(s), angle(s), wavelength(s), etc., detection polarization(s), angle(s), wavelength(s), etc.) of the imaging subsystem.

In a similar manner, the output generated by the electron beam subsystem may include images generated by the electron beam subsystem with two or more different values of a parameter of the electron beam subsystem. The multiple modes of the electron beam subsystem can be defined by the values of parameters of the electron beam subsystem used for generating images for a specimen. Therefore, modes that are different may be different in the values for at least one of the electron beam parameters of the electron beam subsystem. For example, in one embodiment of an electron beam subsystem, different modes may use different angles of incidence for illumination.

The imaging subsystem embodiments described herein may be configured for inspection, metrology, defect review, or another quality control related process performed on the specimen. For example, the embodiments of the imaging subsystems described herein and shown in FIGS. 1 and 2 may be modified in one or more parameters to provide different imaging capability depending on the application for which they will be used. In one such example, the imaging subsystem shown in FIG. 1 may be configured to have a higher resolution if it is to be used for defect review or metrology rather than for inspection. In other words, the embodiments of the imaging subsystems shown in FIGS. 1 and 2 describe some general and various configurations for an imaging subsystem that can be tailored in a number of manners that will be obvious to one skilled in the art to produce imaging subsystems having different imaging capabilities that are more or less suitable for different applications.

The imaging subsystems described above are configured for scanning energy (e.g., light, electrons, etc.) over a physical version of the specimen thereby generating images for the physical version of the specimen. In this manner, the imaging subsystems may be configured as “actual” subsystems, rather than “virtual” subsystems. However, a storage medium (not shown) and computer subsystem(s) 102 shown in FIG. 1 may be configured as a “virtual” system. In particular, the storage medium and the computer subsystem(s) may be configured as a “virtual” inspection system as described in commonly assigned U.S. Pat. No. 8,126,255 issued on Feb. 28, 2012 to Bhaskar et al. and U.S. Pat. No. 9,222,895 issued on Dec. 29, 2015 to Duffy et al., both of which are incorporated by reference as if fully set forth herein. The embodiments described herein may be further configured as described in these patents.

As mentioned above, the one or more components that are executed by the one or more computer subsystems include a DL model, e.g., DL model 104 shown in FIG. 1. Generally speaking, “deep learning” (also known as deep structured learning, hierarchical learning or deep machine learning) is a branch of machine learning (ML) based on a set of algorithms that attempt to model high level abstractions in data. In a DL-based model, there are typically many layers between the input and output, allowing the algorithm to use multiple processing layers, composed of, for example, multiple linear and non-linear transformations. DL methods are based on learning representations of data. An observation (e.g., an image) can be represented in many ways such as a vector of intensity values per pixel, or in a more abstract way as a set of edges, regions of particular shape, etc.

A DL model can also be generally defined as a model that is probabilistic in nature. In other words, a DL model is not one that performs forward simulation or rule-based approaches and, as such, a model of the physics of the processes involved in generating an actual image is not necessary. Instead, as described further herein, the DL model can be learned (in that its parameters can be learned) based on a suitable training set of data.

Many semiconductor quality control type applications currently used in the art provide improved results by using design data to perform certain functions like defect detection and classification among others. In order for the design data to be useful for any of these functions, it has to be properly aligned to the results generated for a specimen by the quality control tool. For example, unless a specimen image is properly aligned to design data, which parts of the image correspond to which parts of the design cannot be accurately determined. One difficulty in performing such alignment is that a specimen image often does not much look like its corresponding design, which can be due to a number of factors including how the structures in the design are formed on the specimen and the ability of the tool to image the structures. In other words, specimen images can have substantially different image characteristics than corresponding design data, which can make aligning the corresponding specimen images and design data particularly difficult. In most cases, it is impossible to change the characteristics of the specimen images to make image-to-design alignment easier. Therefore, creative and better ways to make that alignment possible are constantly being explored. The embodiments described herein advantageously provide better alignment for specimens that have a design to image mismatch such as that described above.

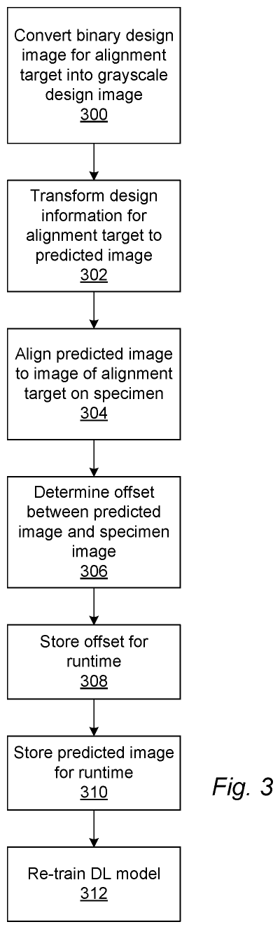

The one or more computer subsystems are configured for transforming design information for an alignment target on a specimen to a predicted image of the alignment target by inputting the design information into the DL model, as shown in step 302 of FIG. 3. The one or more computer subsystems may input the design information into the DL model in any suitable manner. The DL model then transforms the input design information to a predicted image of the alignment target that approximates an image of the alignment target formed on a specimen that would be generated by an imaging subsystem such as that described herein. The DL model therefore transforms the design information from a design space to a specimen image space. In this manner, the input and output of the DL models described herein are in different domains, i.e., design data space vs. specimen image space.

The input design information may therefore be significantly different than the output predicted image. In particular, the input and output of the transformation process may have significantly different image characteristics. However, by appropriate training of the DL model, which may be performed as described further herein, the predicted image of the alignment target generated by the DL model will have substantially the same image characteristics as the actual image of the alignment target formed on the specimen generated by an imaging subsystem. In other words, when the DL model is properly trained, the predicted image will be indistinguishable (or nearly indistinguishable) from the corresponding real image of the specimen generated by the imaging subsystem.

For ease of understanding, images of the specimen that are generated by an imaging subsystem may be referred to herein simply as “real images” or “actual images,” meaning that they are generated by some system that includes imaging hardware rather than only by modeling as would be the predicted images.

In one embodiment, the DL model is configured as a variational autoencoder (VAE). In this manner, the embodiments described herein provide DL VAE predicted optical images from design and their use in pixel-to-design alignment (PDA). The embodiments described herein also provide a complete method/flow to perform PDA using a DL based method on tools such as those described further herein. While certain embodiments are described herein with respect to a VAE (which is used interchangeably with the term “VAE model”), the embodiments are not limited to a VAE model. DL models other than VAEs can be used in the embodiments described herein. In general, the VAE may have a configuration such as that described further herein or any suitable configuration known in the art. Additional information on VAEs can be found in “Tutorial on Variational Autoencoders,” Doersch, arXiv:1606.05908, Aug. 13, 2016, 23 pages, which is incorporated by reference as if fully set forth herein. The embodiments described herein may be further configured as described in this reference.

In one embodiment, the one or more computer subsystems are configured for converting a binary design image for the alignment target into a grayscale design image, as shown in step 300 of FIG. 3, and the design information includes the grayscale design image and not the binary design image. For example, design data images generated directly from design data are usually binary representations of the polygons in the design (e.g., black polygons on a white background or vice versa). The computer subsystem(s) may rasterize the binary design image to convert the design polygons to a grayscale image. The rasterized grayscale image may then be input to the DL model as described further herein to generate a predicted image. The original binary design data image then does not need to be input to the DL model, but in some cases, inputting the original binary design data image into the DL model with the rasterized grayscale image (e.g., as another channel of input) may be useful.

Using rasterized design images as the DL model input instead of binary design images is an important new feature of the embodiments described herein. In the case of an optical imaging subsystem, the real optical images have limited pixel size (e.g., 30 nm). In contrast, design polygons have subpixel resolution. A binary design image with the same pixel size as an optical image has +/−0.5 pixel uncertainty. Rasterized images are much more accurate representations of design polygons. For example, rasterized grayscale images can have the same pixel size as the real specimen images. Internally, the computer subsystem(s) may perform database (DB) raster using 1/32 pixel size to represent polygons, then apply proper low-pass filtering to generate the rasterized image. A pixel may be assigned a grayscale value of 255 if the pixel is “way inside the polygon.” In contrast, a pixel may be assigned a grayscale value of 0 if the pixel is “way outside the polygon.” If the pixel is relatively close to the polygon edge, for example, within 1 pixel or a half of a pixel, then the intensity may be a linear function (e.g., edge speed) of the distance to the polygon edge. Of course, any suitable method for generating rasterized design images from binary design images may be used to generate input to the DL models described herein.

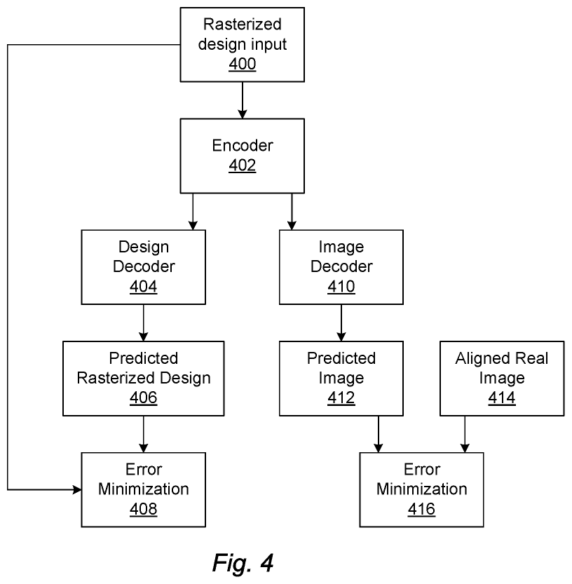

FIG. 4 shows one embodiment of a VAE architecture that may be used in the embodiments described herein. The VAE architecture may include one encoder layer and more than one decoder layer. The computer subsystem may generate rasterized design input 400 that is input to encoder 402. The encoder may have any suitable configuration known in the art and may include any suitable number of layers (e.g., 4) and any suitable type of layers known in the art (e.g., convolutional, pooling, etc.). The output of the encoder may be input to both design decoder 404 and image decoder 410. The encoder extracts features from the rasterized design input with reduced dimensions which keeps maximum information when encoding. For instance, the original input image dimensions may be 192×192. The dimensions of the encoder output may be 12×12.

The decoders may have any suitable configuration known in the art and may include any suitable number of layers (e.g., 4) and any suitable type of layers known in the art (e.g., convolutional, pooling, etc.). Image decoder 410 generates predicted image 412 from the output of the encoder. In this manner, the VAE predicts images from design.

In some embodiments, predicted image 412 and aligned real image 414 are input to error minimization step 416. Both the rasterized design input and the aligned real images may be generated before training of the VAE model. The aligned real images may be specimen images generated by the imaging subsystem that have been aligned to design. For example, initial aligned (optical or other) images may be generated using normalized cross correlation (NCC) measured offsets and/or currently used partial coherent model (PCM) based PDA offsets. In particular, generating aligned real images to design may be performed by shifting real specimen images using offsets measured by NCC between rasterized design and specimen images and/or by shifting real specimen images using offsets measured by NCC between PCM generated images from design and real specimen images.

The error minimization step may minimize the mean square error (or another error function) between the predicted image and the aligned real image. In particular, step 416 may minimize the mean square error of every difference pixel between the real and predicted images. This minimization step may only be used during training of the VAE model where one or more parameters of the model are modified until there is no error (or error below some predetermined threshold) between the predicted image and the aligned real image. This step may however also be used after training to monitor the performance of the VAE model (e.g., to determine if updating, modifying, or retraining of the VAE model has become necessary). For example, if differences between the aligned real images and the predicted images are detected by the error minimization step and greater than some predetermined criteria, then the VAE model may be updated, modified, or retrained, which may be performed as described further herein.

In another embodiment, the DL model is also configured for transforming the grayscale design image into a predicted grayscale design image. For example, the VAE may generate predicted specimen images and predicted rasterized designs from rasterized design inputs, which may include multiple layers of design as described further herein. As shown in FIG. 4, the VAE may include design decoder 404, which may generate predicted rasterized design 406 from the output of encoder 402. Predicted rasterized design 406 and rasterized design input 400 may be input to error minimization step 408. This minimization step may include minimizing cross-entropy error (or another suitable type of error function) between the predicted rasterized design and the rasterized design input. In other words, step 408 may include minimizing cross-entropy reconstruction error between input and generated design, which may be performed in any suitable manner known in the art.

The input and output rasterized designs are not then necessarily the same. In particular, the rasterized design input is generated by design polygons directly without using any type of DL modeling such as that described further herein. The predicted rasterized design is the output from the VAE DL model. By minimizing the cross-entropy (or other) error between the input rasterized design and the predicted rasterized design, the encoder layers may be regulated, which will help to generate better and/or more stable predicted images. In this manner, the predicted rasterized design may be generated and output to control the behavior of the encoder. Unlike error minimization 416, which may only be used during training but may optionally be used during runtime as well, error minimization step 408 may be performed during both training and runtime.

In some embodiments, the design information includes information for multiple layers of a design for the specimen. In this manner, the embodiments described herein may be configured for VAE based image generation using multiple layers of design. For example, the VAE models described herein support multiple layers of design. The DL model may be configured to handle multiple layers of design in the same manner that it might handle multiple other information streams, like multiple channels of colors. For example, the input to the VAE model may be changed from something like (width, height, 1) to (width, height, nLayers). Multiple layers of design as that term is used herein generally refers to layers formed one on top of the other on a specimen or one after the other on the specimen. Therefore, the different layers of the design may include information for different polygons formed on the specimen in different steps of a fabrication process. The multiple layers that are used in the predictions described herein may not include all of the layers of the design formed up to the point at which the specimen is imaged. For example, the layers of design that are input to the DL model may include only those layers that are expected to have at least some effect on the images of the specimen generated by an imaging subsystem. Generating or predicting images from multiple layers of design may result in predicted images that better resemble real specimen images.

In one such embodiment, the DL model is configured to have different weights for at least two of the multiple layers that are separately determined during training of the DL model. For example, some design layers will most likely contribute more than others in generating/predicting specimen images. The first and last VAE convolutional layers may have mode filter coefficients to train. These coefficients may control the relative weights of each design layer. The weight applied to each layer may be learned during the VAE model training, which may be performed as described further herein.

The DL models described herein may or may not be trained by the one or more computer subsystems and/or one of the component(s) executed by the computer subsystem(s). For example, another method or system may train the DL model, which then may be stored for use as the component(s) executed by the computer subsystem(s). The DL model may also be trained or built anytime prior to runtime (e.g., during PDA training or setup). The DL models described herein may also be updated, retrained, or revised at any time after setup and/or deployment of a trained model. Once the VAE model has been trained, it may be used by the embodiments described herein to generate predicted specimen images from rasterized design images on all selected locations.

The computer subsystem(s) may select alignment target(s) for use in training and/or runtime from setup images of the specimen generated with the imaging subsystem. The alignment target(s) selected for training and runtime may or may not be the same. For example, training and runtime may be performed using the same alignment target, but with fewer instances of the alignment target for training versus runtime. The opposite is also possible. The selected alignment target(s) may also include different alignment targets having different characteristics other than just different positions on the specimen or in the design. The alignment target(s) may be selected in any other suitable manner known in the art. Alternatively, another system or method may select the alignment target(s), and the computer subsystem(s) may acquire information for the selected alignment target(s) in any suitable manner. The embodiments described herein may also be used with any suitable alignment targets known in the art that are selected in any suitable manner known in the art.

The one or more computer subsystems may receive the design data for each of the alignment target(s) in any suitable manner such as by searching a design for the specimen based on information for the alignment target(s), by requesting a portion of a design (e.g., a design clip) at the position(s) of the alignment target(s) from a storage medium or computer system that contains the design data, etc. The design data that is received by the one or more computer subsystems may include any of the design, design data, or design information described further herein.

The VAE models described herein may be trained using a relatively small set or sets of training data, which may include design information (or rasterized design images) and corresponding aligned specimen images, which may be generated as described above with respect to FIG. 4. The training set may be used by the computer subsystem(s) in any suitable manner known in the art including being split into subsets for training and verification, being updated, modified, or replaced over time or when the process changes, etc.

A DL model may then be trained based on a training set that includes rasterized design images with corresponding aligned real specimen images. Both the specimen images and the rasterized design images are the training inputs. The training may include inputting the training inputs into the DL model and altering one or more parameters of the DL model until the output produced by the DL model matches (or substantially matches) the training inputs. Training may include altering any one or more trainable parameters of the DL model. For example, the one or more parameters of the DL model that are trained by the embodiments described herein may include one or more weights for any layer of the DL model that has trainable weights. In one such example, the weights may include weights for convolution layers but not pooling layers.

Although some embodiments are described herein with respect to a DL model, the embodiments described herein may include or use multiple DL models. In one such example, different DL models may be trained and used as described herein for different modes, respectively, of the imaging subsystem. For example, alignment performed for one mode may not necessarily be transferrable to another mode. In other words, by performing alignment for one mode, not all of the modes may be aligned to design (or at least not aligned to design with sufficient accuracy). In most cases, different modes of an imaging tool will produce images that are different from each other in one of several possible ways, e.g., noise levels, contrast, resolution, image type (e.g., DF vs. BF, optical vs. electron beam, etc.), and the like. Therefore, if a DL model is trained for one mode of a tool, chances are it will be unsuitably trained to transform information for another mode of the tool. As such, multiple DL models may be separately and independently trained, one for each mode of interest, and image-to-design alignment may be separately and independently performed for different modes used in a single process performed on a specimen. In this manner, when different modes are used to generate images for a specimen, the images generated in more than one mode may be aligned to the design for the specimen. The same pre-trained DL model may be used for each mode although that is not necessary. Each trained DL model may then be used to perform mode specific transformations. The design information input to each differently trained DL model may be the same design information since the design of the specimen will not change from mode to mode. Different rasterized images may be input to the different DL models though when appropriate.

The DL model is trained to produce predicted images that cannot be distinguished from real specimen images. Experiments performed by the inventors have shown that VAE generated images are better for align-to-design than images predicted by existing methods. For example, experiments performed by the inventors showed that VAE generated images are closer to real specimen images than PCM generated images. In particular, the inventors generated X/Y projections of PCM and VAE generated images that show the closer resemblance of the VAE generated images to the real specimen images. In this manner, the DL based PDA described herein can generate/predict images with closer resemblance to real specimen images and can be used to achieve more accurate PDA. In addition, shrinking design rules may present difficulties for predicting images by PCM, and other currently used methods may run into difficulties that are not an issue for the DL models described herein.

Once the DL model is trained, it can be used to transform design information for an alignment target to a predicted image. For example, the one or more computer subsystems may acquire design data or a rasterized design image for each target which may be performed as described further herein. The one or more computer subsystems may then create a predicted patch image from design at each target through the trained DL model. In this manner, a DL model described herein may be used to generate predicted specimen images for any given design clip, which will then be used for aligning the specimen images to calculate the offset, as described further herein. In other words, after training, the DL model may be used to create predicted specimen images for PDA so that the actual specimen images can be aligned to the predicted specimen images and thereby their corresponding design clips.

The one or more computer subsystems are also configured for aligning the predicted image to an image of the alignment target on the specimen generated by an imaging subsystem, as shown in step 304 of FIG. 3. For example, the one or more computer subsystems may align the predicted image and the specimen image at one or more (or each) targets. Aligning predicted images to real images may be performed based on a normalized sum of squared differences (NSSD). For example, NSSD of the predicted image and the specimen image may be used to calculate alignment offset. NSSD may be performed using any suitable method, algorithm, function, etc. known in the art. The aligning step may however be performed using any other suitable alignment method or algorithm known in the art.

The one or more computer subsystems are further configured for determining an offset between the predicted image and the image generated by the imaging subsystem based on results of the aligning, as shown in step 306 of FIG. 3. In this manner, the embodiments described herein may use VAE generated predicted images to measure PDA offsets. This offset may be determined in any suitable manner and may be expressed in any suitable manner (e.g., as a Cartesian offset, as a two-dimensional function, etc.). For example, the computer subsystem(s) may identify PDA offsets between VAE predicted images and real specimen images for all selected locations by using NCC for measuring individual offsets.

The transforming and aligning steps may be performed for additional alignment targets on the specimen, and determining the offset may include determining different offsets for different frames, jobs, sub-swaths, swaths, etc., of images generated for the specimen by the imaging subsystem during the process. For example, the one or more computer subsystems may determine design-to-image offsets for each inspection frame from targets. Compared to currently used methods and systems for PDA, the VAE models described herein may advantageously generate more predicted images for selected wafer die locations, which may then be used to align specimen images to design. In this manner, the VAE model may be used to generate predicted images using rasterized design from all selected locations of a die.

Being able to use more selected locations for alignment means better PDA across an entire die or wafer that can follow image jitter or other sources of error in alignment. Experiments were performed by the inventors to compare NCC peak values and alignment offsets for PCM based PDA and VAE based PDA. In particular, align offset X values, align offset Y values, and NCC peak values were determined and plotted as a function of test index on the X axis. The test index on the X axis corresponds to real images/designs selected from adjacent close locations along die location in X. The distance along X between adjacent index values is close enough to capture the image jitter change. VAE alignment offset X and Y values were measured using NCC between real specimen images and VAE predicted images. PCM alignment offsets in X and Y were measured using NCC between real specimen images and PCM generated images. At almost every data point examined by the inventors, the VAE based PDA exhibited higher NCC peak values than the PCM based PDA, corresponding to more accurate offset measurements. In other words, the experiments performed by the inventors showed that VAE based PDA can generate more accurate alignment offsets than the currently used PDA methods. In addition, the VAE based PDA results showed significantly smoother offsets in both X and Y across all test index values, indicating more accurate alignment as image jitter is gradually changed and can be measured at adjacent locations.

Additional experiments performed by the inventors include a wafer comparison of VAE measured offsets and currently used PDA offsets from one sub-swath on an inspection tool. The offsets in pixels between optical-to-design in both X and Y were plotted as a function of die relative location in X. The optical-to-design alignment offsets are mainly due to image jitter which should change smoothly across the entire die of the entire sub-swath. The plotted results showed that the VAE offsets, and VAE offsets in between scattered currently used PDA offsets, are smoother in Y, indicating that VAE offsets are more accurate than currently used PDA offsets.

The inventors also generated a similar plot for another wafer comparison of VAE measured offsets and currently used PDA offsets from one swath on an inspection tool. In the same manner described above, the optical-to-design alignment offsets are mainly due to image jitter which should change smoothly across the entire die of the entire swath. The plotted results showed that the VAE offsets were smoother compared to the currently used PDA offsets, indicating that the VAE offsets are more accurate than currently used PDA offsets. Similar results were shown in a similar plot generated from VAE offsets from an entire swath of a die.

The computer subsystem(s) may be configured for determining PDA offsets for VAE predicted images to real specimen images for all selected locations and clustering the PDA offsets to generate robust offsets. In this manner, the PDA offsets determined and used by the embodiments described herein may be either clustering or individual offsets. Adding clustering to VAE based PDA can produce even better results than using individual offsets. In one such embodiment, the alignment target is one of multiple alignment targets located in a swath of images generated by the imaging subsystem, and the one or more computer subsystems are configured for performing the transforming, aligning, determining, and storing steps for the multiple alignment targets, clustering the offsets determined for the multiple alignment targets to generate a clustered offset, and replacing one or more of the offsets determined for the multiple alignment targets with the clustered offset. In this manner, clustering may be used to process offsets for each swath on the swath level. In other words, clustering may be separately performed for each swath of images generated for the specimen. Clustering may, however, be performed on a different frequency basis such as for less than all of the swath, for multiple swaths, for an entire specimen, etc.

After clustering, incorrect individual offsets may be replaced with the clustered offset. For example, if an offset determined for one of the alignment targets falls clearly outside of the clustered offsets, that offset may be replaced with a clustered offset. In this manner, the robustness of the offsets may be improved via the clustering. The robust offsets, after the clustering, can then be used as described herein such as to substantially accurately place design on top of optical images during runtime for inspection.

The embodiments described herein may also be configured for bandpass filtering the predicted and real images prior to alignment, offset determination, etc. In this manner, PDA offsets may not be measured directly from rendered and real images, but after bandpass filtering of these images, which may be performed in any suitable manner known in the art. Both the rendered and real images may be processed using bandpass filtering to improve alignment offset measurement accuracy. Any other suitable image filtering may also or alternatively be performed on the predicted and real images prior to alignment and offset determination to improve the alignment offset measurement accuracy. Whether the offsets are measured directly from the predicted and real images or after the predicted and real images have been bandpass (or other) filtered, the offsets may be measured using NCC or another suitable method.

The one or more computer subsystems are also configured for storing the determined offset as an align-to-design offset for use in a process performed on the specimen with the imaging subsystem, as shown in step 308 in FIG. 3. The computer subsystem(s) may store the align-to-design offset in any suitable computer-readable storage medium. The align-to-design offset may be stored with any of the results described herein and may be stored in any manner known in the art. The storage medium may include any storage medium described herein or any other suitable storage medium known in the art. After the align-to-design offset has been stored, the align-to-design offset can be accessed in the storage medium and used by any of the method or system embodiments described herein, formatted for display to a user, used by another software module, method, or system, etc. The determined offset may also be stored indefinitely, as in with the results of the process in which it is used, or temporarily, as in only as long as it is needed to perform PDA in the process in which it is used.

When the transforming and aligning steps are performed for additional alignment targets on the specimen, determining the offset may include determining different offsets for different frames, etc. of images generated for the specimen by the imaging subsystem during the process, and storing the determined offset includes storing the different offsets. In another embodiment, the one or more computer subsystems are configured for storing the predicted image of the alignment target as shown in step 310 of FIG. 3. For example, the one or more computer subsystems may save predicted images and corresponding offsets to a database for runtime inspection (or another process described herein). These steps may be performed as described further herein.

The embodiments described herein may set up alignment of a specimen for a process recipe, which may be performed as part of setting up, creating, calibrating, or updating the recipe. That recipe may then be stored and used by the embodiments described herein (and/or another system or method) to perform the process on the specimen to thereby generate information (e.g., defect information) for the specimen. In this manner, the align-to-design offset may be generated and stored once per specimen layer and/or on a per specimen basis. In this manner, the predicted images and determined offsets generated by the embodiments described herein may only be used for a single specimen.

As described herein, therefore, the embodiments can be used to setup a new process or recipe. The embodiments may also be used to modify an existing process or recipe, whether that is a process or recipe that was used for the specimen or was created for one specimen and is being adapted for another specimen. In addition, the embodiments described herein are not limited to inspection process creation or modification. For example, the embodiments described herein can also be used to setup or modify a process for metrology, defect review, etc. in a similar manner. In particular, determining an offset for use in a process and performing specimen-to-design alignment as described herein can be performed regardless of the process that is being setup or revised. The embodiments described herein can therefore be used not just for setting up or modifying an inspection process but can be used for setting up or modifying any quality control type process performed on the specimens described herein.

The embodiments described herein may also perform the process after the specimen has been aligned in runtime as described herein. In one embodiment, the process is an inspection process. However, the process may include any of those described herein such as inspection, defect review, metrology, and the like. The computer subsystem(s) may be configured for storing information for the specimen generated by performing the process such as information for detected defects in any suitable computer-readable storage medium. The information may be stored with any of the results described herein and may be stored in any manner known in the art. The storage medium may include any storage medium described herein or any other suitable storage medium known in the art. After the information has been stored, the information can be accessed in the storage medium and used by any of the method or system embodiments described herein, formatted for display to a user, used by another software module, method, or system, etc.

In one such embodiment, the one or more computer subsystems are configured for performing the process on the specimen with the imaging subsystem and performing the inputting, aligning, determining, and storing during the process, and the offset is a runtime-to-design offset. For example, during the process, the one or more computer subsystems may generate a predicted image for each target and align the predicted image to a runtime image at each target. The one or more computer subsystems may determine offsets between predicted and runtime for each inspection frame, each swath, each sub-swath, etc. All of these steps may be performed as described further herein.

Unlike some currently used methods for alignment setup and runtime, therefore, the embodiments described herein do not need additional steps like generating setup alignment target images, determining runtime-to-setup offsets, modifying an align-to-design offset with the runtime-to-setup offset to get a runtime-to-design offset, and the like. In other words, because predicted images can be generated during runtime by the embodiments described herein from the design information for the alignment targets, the embodiments described herein can simply generate the predicted images during runtime and then align the predicted images to the runtime images to get runtime-to-design offsets.

Therefore, because the image predictions can be done so fast by the VAE models described herein, the embodiments can reduce the complexity of the alignment process by eliminating a number of steps currently performed for image alignment, which can also substantially increase the accuracy of the offsets determined by the embodiments described herein. In this manner, once a VAE model has been trained as described herein, that trained VAE model can be used during runtime to predict images for alignment until any retraining of the VAE model is needed or desired. Therefore, although the predicted images may be saved by the one or more computer subsystems for any variety of reasons, unlike currently used methods in which the predicted images are saved during setup and then reused during runtime, the embodiments described herein do not require such image storage and reuse. For example, in one embodiment, the one or more computer subsystems are configured for training the DL model and setting up the process, and the training and setup up do not include storing a setup predicted image of the alignment target for use in the process performed on the specimen with the imaging subsystem.

To reiterate some important differences between VAE based PDA and existing PDA then, an existing PDA flow in training may include generating PCM rendered/predicted images and measuring offsets A between optical images from training and PCM rendered images. These offsets A are between optical images from training and design. During training, existing PDA saves a PDA database, which includes offsets A and optical images from each alignment target/alignment target location. In runtime, existing PDA identifies offsets B between optical images in runtime and optical images in training. Offsets A and B are then added together to generate final offsets from runtime optical to design.

In contrast, the VAE PDA flow performed by the embodiments described herein may include, during training, generating an initial VAE model and saving alignment target location information. During runtime, the embodiments may run the VAE model to predict VAE generated specimen images for each target location. The embodiments measure offsets between runtime specimen images and VAE generated predicted images. These offsets are runtime specimen image to design offsets. The VAE model may be updated in one or more ways during runtime as described further herein, e.g., if process variation is relatively severe between the initial training specimen or specimen used for previous model training/updating and the current specimen.

In another such embodiment, the process includes placing design care areas accurately on top of inspection images by shifting design care area or inspection image using runtime-to-design offset. For example, the one or more computer subsystems may place care areas according to offset correction. “Care areas” as they are commonly referred to in the art are areas on a specimen that are of interest for inspection purposes from design. Sometimes, care areas are used to differentiate between areas on the specimen that are inspected from areas on the specimen that are not inspected in an inspection process. In addition, care areas are sometimes used to differentiate between areas on the specimen that are to be inspected with one or more different parameters. For example, if a first area of a specimen is more critical than a second area on the specimen, the first area may be inspected with a higher sensitivity than the second area so that defects are detected in the first area with a higher sensitivity. Other parameters of an inspection process can be altered from care area to care area in a similar manner.

In these embodiments, the one or more computer subsystems may use 0 care area border in x and y directions. For example, because the embodiments described herein can align specimen images to design with substantially high accuracy, the care areas can be located in the specimen images with substantially high accuracy. Therefore, a border, which is commonly used to increase a care area artificially to account for any errors in care area placement, can be effectively eliminated by the embodiments described herein. Placing the care areas with such high accuracy and eliminating the care area border is advantageous for a number of reasons including that the detection of nuisance on the specimen can be significantly reduced and the detection of defects of interest (DOIs) on the specimen can be improved.

In one embodiment, the one or more computer subsystems are configured for performing the inputting, aligning, determining, and storing during runtime of the process performed on the specimen and during runtime of the process performed on one or more other specimens. For example, the DL based PDA described herein can be efficiently implemented on graphics processing unit (GPU) hardware and can be faster than PCM based PDA. In this manner, the steps described herein may be performed in runtime for each scan of each specimen. In particular, since the DL based approaches described herein can be easily achieved on GPU with faster throughput, the embodiments described herein can be used in runtime PDA on tools such as those described herein. As described further herein, being able to perform the steps described herein in runtime means that the embodiments have fewer steps and are simpler than currently used PDA methods, which can also cause the embodiments described herein to have better alignment accuracy.

In some embodiments, the one or more computer subsystems are configured for re-training the DL model, as shown in step 312 of FIG. 3, for a different specimen by performing iterative training of the DL model. For example, iterative VAE model training may be performed when there are process variations on new specimens. Process variations between specimens may produce differences such as color variation, blurred images due to defocus conditions, etc. in the images of the specimens generated by the imaging subsystem. These process variations may or may not be defects on the specimen but may cause problems for PDA that is setup with one specimen and used for one or more other specimens. In this manner, the VAE model may be re-trained using iterative VAE model training.

The iterative VAE model training may be performed for each additional specimen that is scanned and aligned using the PDA setup with another specimen. Alternatively, the iterative VAE model training may only be performed after certain intervals, which may be based on time, number of specimens, etc. The iterative VAE model training may also be performed when it is suspected or known that there has been some process variation between specimens. The computer subsystem(s) may also determine if iterative VAE model training should be performed based on real specimen images generated by the imaging subsystem, e.g., by comparing them to the VAE predicted images to determine if they are different enough to warrant VAE re-training, updating, modifying, calibrating, etc. or when the alignment results like NCC values drop below a predetermined threshold.

The computer subsystem(s) may train the VAE model iteratively to generate predicted images that better resemble the real specimen images. VAE model training may be performed using a relatively small amount of real specimen images that have been aligned to design to initially train the VAE model, which may be performed as described further herein. The initially trained VAE model may then be used to generate more predicted images from rasterized design. The computer subsystem(s) may then perform NCC between VAE predicted images and real specimen images to measure offsets and then shift the real specimen images by the offset to align to design, which may be performed as described further herein. These steps can generate more real specimen images aligned to design that can then be used for additional training of the VAE model. In other words, iterative VAE model training may include using an existing VAE model to generate predicted images, identifying PDA offsets between predicted images and real images, generating aligned specimen images using those offsets, and using those aligned images and rasterized design images to retrain the VAE model. In this manner, the computer subsystem(s) may use more aligned real specimen images iteratively to better train the VAE model.

In one such embodiment, the one or more computer subsystems are configured for performing the re-training during runtime of the process performed on the different specimen. In this manner, due to the substantially high throughput advantage of the embodiments described herein, the DL model can be updated in runtime to overcome process variation changes. In particular, because the embodiments described herein have such a fast throughput compared to currently used PDA methods, the embodiments can perform all of the steps described herein including iterative training in runtime of the process performed on any specimen.

In another embodiment, the one or more computer subsystems are configured for performing the inputting, aligning, determining, and storing for a first portion of the specimen and re-training the DL model by performing iterative training of the DL model for a second portion of the specimen. For example, in one proposed flow for VAE based PDA, an initial VAE model may be trained during PDA training or setup. A relatively small amount of PCM rendered/generated images from rasterized design at good target locations may be used to generate aligned images. “Good target locations” in this context refers to locations where PCM rendered images can be used to measure substantially accurate offsets between PCM rendered and real specimen images. The computer subsystem(s) may then iteratively train the VAE model from a first couple of swaths (e.g., 5 swaths) scanned on the specimen by the imaging subsystem or the entire specimen. The specimen may then optionally be rescanned with the imaging subsystem and the computer subsystem(s) may use the VAE model to inference images from rasterized design for all target locations to perform PDA alignment as described further herein. In this manner, a VAE model may be generated for a first specimen. An initial VAE model can be trained/generated from the first swath of images. The VAE model can then be retrained using iterative VAE model training from later swaths of images to generate a better VAE model.

In one such embodiment, the one or more computer subsystems are configured for performing the inputting, aligning, determining, and storing for the first portion of the specimen and the re-training during runtime of the process performed on the specimen. For example, the embodiments may be configured for subsequent VAE model updating during PDA runtime. The computer subsystem(s) may use the existing VAE model to render/generate images from rasterized design at selected target locations to generate aligned images. The computer subsystem(s) may iteratively update/train the VAE model from a first couple of swaths of the current scan. The imaging subsystem may then rescan the specimen, and the computer subsystem(s) may use the updated VAE model to inference images from rasterized design for all target locations to perform PDA alignment as described further herein.

In another embodiment, the computer subsystem(s) are configured for performing the process on the specimen with the imaging subsystem, and the process includes aligning a target image of an inspection area on the specimen to a design for the specimen based on the align-to-design offset, as shown in step 500 of FIG. 5, transforming design information for the inspection area to a predicted target image of the inspection area by inputting the design information for the inspection area into the DL model, as shown in step 502 of FIG. 5, subtracting the predicted target image from the aligned target image, as shown in step 504 of FIG. 5, and applying a defect detection method to results of the subtracting, as shown in step 506 of FIG. 5. For example, in addition to performing PDA and care area placement, the embodiments described herein may generate predicted images that can be used as reference images for inspection. In other words, once the VAE models described herein are trained for generating predicted images for alignment targets, the same trained VAE models may be capable of generating predicted images for other portions of the specimen that closely resemble the real images for those portions of the specimen.

In this manner, an inspection process may include setting up a PDA process as described herein or at least performing PDA using a small number of predicted images of one alignment targets on the specimen on which the inspection process is being performed. The results of the alignment process may then be used to align other images to design including any real specimen images generated at any target or inspection areas on the specimen, which may include for example only care areas or any areas that are to be inspected. The trained VAE model may be used prior to the process or during runtime as described herein to generate predicted images for those target or inspection areas.

Since the predicted images are generated from design information, e.g., rasterized design images, the predicted images are essentially database (DB) reference images that can be subtracted from the real images after the predicted and real images have been aligned to each other as described further herein. That subtraction may be performed in any suitable manner known in the art. The results of the subtraction may be a difference image that shows any differences between the predicted and real images.

Inspection may include applying a defect detection method to the difference image to determine if any of the differences are indicative of defects or defect candidates. For example, the defect detection method may include applying a threshold to the difference image, determining that any pixels having values above the threshold are defects or potential defects, and determining that all pixels having values below the threshold are not defects or potential defects. Of course, this is possibly the simplest defect detection method that could be used in the inspection process, and any other suitable defect detection method can be used with the embodiments described herein. In other words, the predicted images generated by the VAE model for inspection areas on a specimen may be used in the same manner as any other reference images in any defect detection methods known in the art. In this manner, the predicted inspection area images described herein are not specific to any particular defect detection method.

In addition to performing PDA, care area placement, and inspection, the embodiments described herein may be useful in any system or method that performs alignment of different types of images to each other and/or information and/or images in different coordinate spaces. One example of such a useful application is for performing image alignment for the generation of a golden grid image such as that described in U.S. Patent Application Publication No. 2022/0067898 by Chen et al. published Mar. 3, 2022, which is incorporated by reference as if fully set forth herein. The embodiments described herein may be further configured as described in this publication.

Results and information generated by performing the processes described herein on the specimen or other specimens of the same type may be used in a variety of manners by the embodiments described herein and/or other systems and methods. Such functions include, but are not limited to, altering a process such as a fabrication process or step that was or will be performed on the specimen or another specimen in a feedback or feedforward manner. For example, the computer subsystem(s) may be configured to determine one or more changes to a process that was or will be performed on a specimen inspected as described herein based on the detected defect(s). The changes to the process may include any suitable changes to one or more parameters of the process. The computer subsystem(s) preferably determine those changes such that the defects can be reduced or prevented on other specimens on which the revised process is performed, the defects can be corrected or eliminated on the specimen in another process performed on the specimen, the defects can be compensated for in another process performed on the specimen, etc. The computer subsystem(s) may determine such changes in any suitable manner known in the art.

Those changes can then be sent to a semiconductor fabrication system (not shown) or a storage medium (not shown) accessible to the computer subsystem(s) and the semiconductor fabrication system. The semiconductor fabrication system may or may not be part of the system embodiments described herein. For example, the computer subsystem(s) and/or imaging subsystem described herein may be coupled to the semiconductor fabrication system, e.g., via one or more common elements such as a housing, a power supply, a specimen handling device or mechanism, etc. The semiconductor fabrication system may include any semiconductor fabrication system known in the art such as a lithography tool, an etch tool, a chemical-mechanical polishing (CMP) tool, a deposition tool, and the like.

The embodiments described herein have a number of advantages in addition to those described further herein. For example, the DL models described herein can predict more accurate specimen images from design than currently used PDA methods. In particular, the DL predicted specimen images generated as described herein are closer to real specimen images than other currently used methods. Experiments performed by the inventors showed this in the higher NCC peak value between DL predicted and real specimen images vs. between PCM predicted and real specimen images as described further herein.

DL predicted images generated as described herein can also be used to generate more accurate PDA results than currently used PDA systems and methods. In addition, the DL based approaches described herein provide substantially accurate PDA performed on defocus images as well. In other words, because of the adaptive nature of the embodiments described herein, even if a specimen image is out of focus, the embodiments described herein can be used to generate a predicted image that is similar enough to the specimen image that PDA can be successfully performed.

The DL based PDA described herein can also be efficiently implemented on GPU and can be faster than currently used methods. The high throughput of these methods enables them to be used in runtime for each specimen scan. The embodiments described herein can therefore improve PDA accuracy on inspection and other tools described herein. Since the DL based approaches described herein can be easily implemented on GPU with faster throughput, the embodiments can be used in runtime PDA on inspection and other tools described herein.

Furthermore, the embodiments described herein can predict closer-to-real specimen images from multiple layers of design. In addition to being beneficial for PDA, this capability makes the embodiments useful in other applications such as defect detection in which a real specimen image is compared to a DL predicted image.

The above described advantages of the embodiments are enabled by a number of important new features described herein. These features include, but are not limited to, a DL based method that can predict more accurate specimen images (e.g., optical inspection tool images) than other currently used methods and systems for PDA. Another new feature is a DL based method that predicts specimen images from rasterized design images. An additional new feature is a DL method for predicting specimen images from multiple layers of design. A further new feature is iterative DL model training for PDA. Another important new feature is the entire flow to generate better PDA results on inspection and other tools.

Each of the embodiments of each of the systems described above may be combined together into one single embodiment.

Another embodiment relates to a computer-implemented method for determining an offset for use in a process performed on a specimen. The method includes the transforming, aligning, determining, and storing steps described further herein. These steps are performed by one or more computer systems. One or more components are executed by the one or more computer systems, and the one or more components include a DL model.

Each of the steps of the method may be performed as described further herein. The method may also include any other step(s) that can be performed by the system, computer system(s), and/or DL models described herein. The computer system(s) may be configured according to any of the embodiments described herein, e.g., computer subsystem(s) 102. The DL model may be configured according to any of the embodiments described herein. In addition, the method described above may be performed by any of the system embodiments described herein.

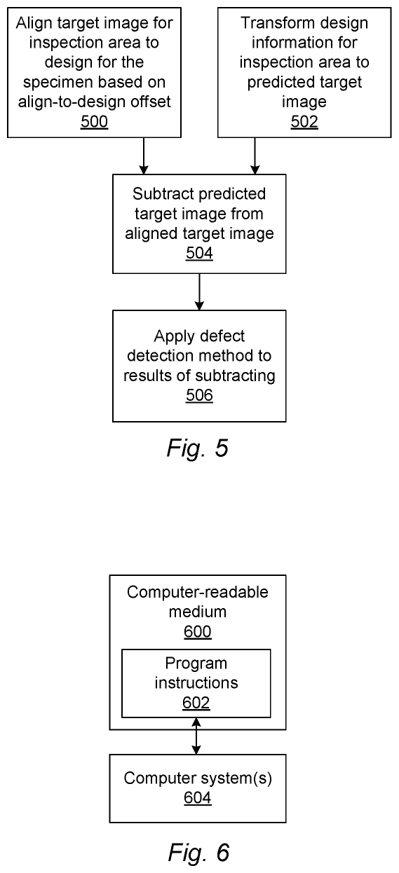

An additional embodiment relates to a non-transitory computer-readable medium storing program instructions executable on one or more computer systems for performing a computer-implemented method for determining an offset for use in a process performed on a specimen. One such embodiment is shown in FIG. 6. In particular, as shown in FIG. 6, non-transitory computer-readable medium 600 includes program instructions 602 executable on computer system(s) 604. The computer-implemented method may include any step(s) of any method(s) described herein.

Program instructions 602 implementing methods such as those described herein may be stored on computer-readable medium 600. The computer-readable medium may be a storage medium such as a magnetic or optical disk, a magnetic tape, or any other suitable non-transitory computer-readable medium known in the art.

The program instructions may be implemented in any of various ways, including procedure-based techniques, component-based techniques, and/or object-oriented techniques, among others. For example, the program instructions may be implemented using ActiveX controls, C++ objects, Python, JavaBeans, Microsoft Foundation Classes (“MFC”), SSE (Streaming SIMD Extension), TensorFlow, CustomOp, CUDA or other technologies or methodologies, as desired.

Computer system(s) 604 may be configured according to any of the embodiments described herein.

Further modifications and alternative embodiments of various aspects of the invention will be apparent to those skilled in the art in view of this description. For example, methods and systems for determining an offset for use in a process performed on a specimen are provided. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1. A system configured to determine an offset for use in a process performed on a specimen, comprising:
one or more computer subsystems; and
one or more components executed by the one or more computer subsystems, wherein the one or more components comprise a deep learning model; and
wherein the one or more computer subsystems are configured for:
transforming design information for an alignment target on a specimen to a predicted image of the alignment target by inputting the design information into the deep learning model;
aligning the predicted image to an image of the alignment target on the specimen generated by an imaging subsystem;
determining an offset between the predicted image and the image generated by the imaging subsystem based on results of said aligning; and
storing the determined offset as an align-to-design offset for use in a process performed on the specimen with the imaging subsystem.

2. The system of claim 1, wherein the deep learning model is configured as a variational autoencoder.

3. The system of claim 1, wherein the one or more computer subsystems are further configured for converting a binary design image for the alignment target into a grayscale design image, and wherein the design information comprises the grayscale design image and not the binary design image.

4. The system of claim 3, wherein the deep learning model is further configured for transforming the grayscale design image into a predicted grayscale design image.

5. The system of claim 1, wherein the design information comprises information for multiple layers of a design for the specimen.

6. The system of claim 5, wherein the deep learning model is configured to have different weights for at least two of the multiple layers that are separately determined during training of the deep learning model.

7. The system of claim 1, wherein the one or more computer subsystems are further configured for re-training the deep learning model for a different specimen by performing iterative training of the deep learning model.

8. The system of claim 7, wherein the one or more computer subsystems are further configured for performing the re-training during runtime of the process performed on the different specimen.

9. The system of claim 1, wherein the one or more computer subsystems are further configured for performing the inputting, aligning, determining, and storing for a first portion of the specimen and re-training the deep learning model by performing iterative training of the deep learning model for a second portion of the specimen.

10. The system of claim 9, wherein the one or more computer subsystems are further configured for performing the inputting, aligning, determining, and storing for the first portion of the specimen and the re-training during runtime of the process performed on the specimen.

11. The system of claim 1, wherein the one or more computer subsystems are further configured for performing the inputting, aligning, determining, and storing during runtime of the process performed on the specimen and during runtime of the process performed on one or more other specimens.

12. The system of claim 1, wherein the one or more computer subsystems are further configured for performing the process on the specimen with the imaging subsystem, and wherein the process comprises aligning a target image of an inspection area on the specimen to a design for the specimen based on the align-to-design offset, transforming design information for the inspection area to a predicted target image of the inspection area by inputting the design information for the inspection area into the deep learning model, subtracting the predicted target image from the aligned target image, and applying a defect detection method to results of the subtracting.

13. The system of claim 1, wherein the one or more computer subsystems are further configured for training the deep learning model and setting up the process, and wherein the training and setting up do not comprise storing a setup predicted image of the alignment target for use in the process performed on the specimen with the imaging subsystem.

14. The system of claim 13, wherein the one or more computer subsystems are further configured for performing the process on the specimen with the imaging subsystem and performing the inputting, aligning, determining, and storing during the process, and wherein the offset is a runtime-to-design offset.

15. The system of claim 14, wherein the process further comprises accurately placing care areas on inspection images generated by the imaging subsystem during the process performed on the specimen based on the runtime-to-design offset.

16. The system of claim 1, wherein the alignment target is one of multiple alignment targets located in a swath of images generated by the imaging subsystem, and wherein the one or more computer subsystems are further configured for performing the transforming, aligning, determining, and storing steps for the multiple alignment targets, clustering the offsets determined for the multiple alignment targets to generate a clustered offset, and replacing one or more of the offsets determined for the multiple alignment targets with the clustered offset.

17. The system of claim 1, wherein the process is an inspection process.

18. The system of claim 1, wherein the imaging subsystem is a light-based imaging subsystem.

19. The system of claim 1, wherein the imaging subsystem is an electron beam imaging subsystem.

20. A non-transitory computer-readable medium, storing program instructions executable on one or more computer systems for performing a computer-implemented method for determining an offset for use in a process performed on a specimen, wherein the computer-implemented method comprises:
transforming design information for an alignment target on a specimen to a predicted image of the alignment target by inputting the design information into a deep learning model, wherein one or more components are executed by the one or more computer systems, and wherein the one or more components comprise the deep learning model;
aligning the predicted image to an image of the alignment target on the specimen generated by an imaging subsystem;
determining an offset between the predicted image and the image generated by the imaging subsystem based on results of said aligning; and
storing the determined offset as an align-to-design offset for use in a process performed on the specimen with the imaging subsystem, wherein said inputting, aligning, determining, and storing are performed by the one or more computer systems.

21. A computer-implemented method for determining an offset for use in a process performed on a specimen, comprising:
transforming design information for an alignment target on a specimen to a predicted image of the alignment target by inputting the design information into a deep learning model, wherein one or more components are executed by one or more computer systems, and wherein the one or more components comprise the deep learning model;
aligning the predicted image to an image of the alignment target on the specimen generated by an imaging subsystem;
determining an offset between the predicted image and the image generated by the imaging subsystem based on results of said aligning; and
storing the determined offset as an align-to-design offset for use in a process performed on the specimen with the imaging subsystem, wherein said inputting, aligning, determining, and storing are performed by the one or more computer systems.
